(19) United States
(12) Patent Application Publication
(10) Pub. No.: US 2022/0219680 A1
(43) Pub. Date: Jul. 14, 2022

(54) INFORMATION PROCESSING DEVICE, INFORMATION PROCESSING METHOD, AND NON-TRANSITORY COMPUTER-READABLE MEDIUM STORING INFORMATION PROCESSING PROGRAM

(71) Applicant: TOYOTA JIDOSHA KABUSHIKI KAISHA, Aichi-ken (JP)

(72) Inventors: Kentaroh NAGAYA, Toyota-shi (JP); Yosuke KIMURA, Nisshin-shi (JP)

(21) Appl. No.: 17/558,598

(22) Filed: Dec. 22, 2021

(30) Foreign Application Priority Data
Jan. 14, 2021 (JP) 2021-004328

(51) Int. Cl. B60W 30/08; B60W 40/06; B60W 40/09

(52) U.S. Cl. CPC B60W 30/08; B60W 40/06; B60W 2520/28; B60W 2552/20; B60W 40/09

(57) ABSTRACT

An information processing device including: a detecting section detecting an observed amount relating to a change in acceleration of a vehicle due to a driving operation; an inertial measurement section detecting an actually measured value of acceleration of the vehicle; and an estimating section that determines that the vehicle has collided in a case in which an acceleration difference, which is a difference between an actually measured value of acceleration of the vehicle detected by the inertial measurement section and an estimated value of acceleration of the vehicle derived on the basis of the observed amount, is greater than or equal to a predetermined threshold value.

### CROSS-REFERENCE TO RELATED APPLICATION

This application claims priority under 35 USC 119 from Japanese Patent Application No. 2021-004328 filed on Jan. 14, 2021, the disclosure of which is incorporated by reference herein.

### BACKGROUND

### Technical Field

The present disclosure relates to an information processing device, an information processing method, and a non-transitory computer-readable medium storing an information processing program, which detect the occurrence of impacts relating to collisions of a vehicle from the driving history of the vehicle, and the like.

### Related Art

In market of used vehicles and the like, the value of a used vehicle differs due to the absence/presence of a history of accidents of that used vehicle. Even if a collision is minor (hereinafter called “light collision”), there are cases in which damage that requires repair is inflicted on the vehicle, and, in such cases, dealers and repair shops and the like require sensing of the fact that there was a collision.

When a vehicle collides, the airbags deploy, but, in actuality, airbags deploy only in the small fraction of collisions that are of the extent of damaging the frame of the vehicle body. Accordingly, light collisions must be detected accurately, regardless of the absence/presence of airbag operation.

Japanese Patent Application Laid-Open (JP-A) No. 2012-221407 discloses an evaluation index creating system for vehicles that estimates damage to vehicles by using stationary vibration load to a vehicle body as an index.

However, in the disclosure of JP-A No. 2012-221407, among the forces that are applied to the vehicle, acceleration components that are due to sudden acceleration, sudden braking and the like are not excluded from the acceleration components that are due to light collisions, and therefore, it is difficult to accurately detect light collisions.

### SUMMARY

The present disclosure provides an information processing device, an information processing method, and a non-transitory computer-readable medium storing an information processing program, which may accurately detect light collisions.

A first aspect of the present disclosure is an information processing device including: a detecting section detecting an observed amount relating to a change in acceleration of a vehicle due to a driving operation; an inertial measurement section detecting an actually measured value of acceleration of the vehicle; and an estimating section that determines that the vehicle has collided in a case in which an acceleration difference, which is a difference between an actually measured value of acceleration of the vehicle detected by the inertial measurement section and an estimated value of acceleration of the vehicle derived on the basis of the observed amount, is greater than or equal to a predetermined threshold value.

The estimated value of the acceleration, which is derived on the basis of an observed amount relating to a change in the acceleration of the vehicle due to a driving operation, is the estimated value of the acceleration of the vehicle due to a driving operation. Further, the acceleration of the vehicle that arises at the time of a collision differs from a change in acceleration that is due to a driving operation. Accordingly, it can be determined that the vehicle has collided in a case in which the difference between the actually measured value of the acceleration of the vehicle that is detected by the inertial measurement section, and an estimated value of the acceleration of the vehicle that is derived on the basis of an observed amount relating to a change in the acceleration of the vehicle due to a driving operation, is greater than or equal to a predetermined threshold value.

In accordance with the information processing device of the first aspect, even in a light collision, divergence can arise between the actually measured value and the predicted value of the acceleration, and therefore, a collision of the vehicle may be inferred accurately.

In a second aspect of the present disclosure, in the above-described first aspect may be configured such that, in a case in which acceleration relating to the acceleration difference is acceleration that is inputted to the vehicle from a road surface through a tire, the estimating section does not employ the estimated value in determining a collision of the vehicle.

In accordance with the information processing device of the second aspect, a collision of the vehicle may be inferred accurately by not using input, which is from the road surface through a tire and which may be a determining error, as an actually measured value of the acceleration in the determining of a collision.

In a third aspect of the present disclosure, in the above-described second aspect, the detecting section may include a wheel speed detecting section that detects respective wheel speeds of four wheels that the vehicle has, and the estimating section may derive wheel speed differences that are respective differences between actually measured values of respective wheel speeds of the four wheels that are front and rear wheels of the vehicle detected by the wheel speed detecting section, and estimated values of respective wheel speeds of the four wheels derived on the basis of the observed amount, and, after a change in the wheel speed difference, in either of a case in which the acceleration difference changes or a case in which wheel speed differences of the front wheels and the rear wheels change in order, the estimating section may determine that acceleration relating to the acceleration difference is acceleration inputted from a road surface through a tire. Due to the above, components which may give rise to a determining error may be excluded from the acceleration.

In a fourth aspect of the present disclosure, in the above-described second aspect, the detecting section may include an imaging section that acquires image data of a periphery of the vehicle in time series, and the estimating section may consider acceleration, which relates to the acceleration difference at a time when sudden behavior of the vehicle is recorded in the image data acquired by the imaging section, to be acceleration that is inputted to the vehicle from a road surface through a tire.

In a fifth aspect of the present disclosure, in the above-described second aspect, the estimating section, in a case in which vertical direction displacement of position information of the vehicle derived on the basis of information from a satellite is greater than or equal to a predetermined value, may determine that acceleration, which relates to the acceleration difference, is acceleration that is inputted from a road surface through a tire.

In a sixth aspect of the present disclosure, in the above-described second aspect, the estimating section may refer to a database of places at which there are undulations of a road surface, places at which a slope changes sharply, and places at which changes in acceleration arise at plural vehicles, and may determine that acceleration relating to the acceleration difference is acceleration inputted from a road surface through a tire.

In a seventh aspect of the present disclosure, in the above-described aspects, the inertial measurement section may detect acceleration in a longitudinal direction and acceleration in a lateral direction of the vehicle respectively, and the estimating section may respectively derive an estimated value of acceleration in the longitudinal direction and an estimated value of acceleration in the lateral direction of the vehicle on the basis of the observed amount, and may determine that the vehicle has collided, in a case in which either of a difference between an actually measured value of acceleration in the longitudinal direction of the vehicle detected by the inertial measurement section and an estimated value of acceleration in the longitudinal direction of the vehicle, or a difference between an actually measured value of acceleration in the lateral direction of the vehicle detected by the inertial measurement section and an estimated value of acceleration in the lateral direction of the vehicle, is greater than or equal to a predetermined threshold value.

The information processing device of the seventh aspect may determine that there is a collision of the vehicle, in a case in which either of, a difference between an actually measured value and an estimated value of acceleration in the longitudinal direction of the vehicle, or a difference between an actually measured value and an estimated value of acceleration in the lateral direction of the vehicle, is greater than or equal to a predetermined threshold value.

In an eighth aspect of the present disclosure, in the above-described seventh aspect, the estimating section may estimate a damage direction of the vehicle on the basis of a quotient of a difference between the actually measured value of acceleration in the longitudinal direction of the vehicle detected by the inertial measurement section and the estimated value of acceleration in the longitudinal direction of the vehicle, and a difference between the actually measured value of acceleration in the lateral direction of the vehicle detected by the inertial measurement section and the estimated value of acceleration in the lateral direction of the vehicle.

The information processing device of the eighth aspect may estimate the damage direction of the vehicle on the basis of the acceleration in the longitudinal direction and the acceleration in the lateral direction of the vehicle.

In a ninth aspect of the present disclosure, in the above-described aspects, the estimating section may construct a model that estimates acceleration of the vehicle, on the basis of observed amounts relating to changes in acceleration of plural vehicles and actually measured values of acceleration of the plural vehicles, which are acquired in advance.

The information processing device of the ninth aspect constructs an acceleration estimating model by machine learning that is based on so-called big data that is acquired from a large number of vehicles. Therefore, a model that may accurately estimate the acceleration of the vehicle due to driving operation may be constructed.

In a tenth aspect of the present disclosure, in the above-described aspects, the observed amount may include measured values of vehicle motions of the vehicle, and control signals relating to driving operation amounts of the vehicle.

The information processing device of the tenth aspect may construct a model, which accurately estimates acceleration of a vehicle due to driving operation, by providing machine learning with observed amounts relating to changes in accelerations of vehicles due to driving operations.

An eleventh aspect of the present disclosure is an information processing method including: detecting, by a detecting section, an observed amount relating to a change in acceleration of a vehicle due to a driving operation; detecting, by an inertial measurement section, an actually measured value of acceleration of the vehicle; and determining that the vehicle has collided in a case in which an acceleration difference, which is a difference between the actually measured value of acceleration of the vehicle and an estimated value of acceleration of the vehicle derived on the basis of the observed amount, is greater than or equal to a predetermined threshold value.

The estimated value of the acceleration, which is derived on the basis of an observed amount relating to a change in the acceleration of the vehicle due to a driving operation, is the estimated value of the acceleration of the vehicle due to a driving operation. Further, the acceleration of the vehicle that arises at the time of a collision differs from a change in acceleration that is due to a driving operation. Accordingly, it may be determined that the vehicle has collided in a case in which the difference between the actually measured value of the acceleration of the vehicle that is detected by the inertial measurement section, and an estimated value of the acceleration of the vehicle that is derived on the basis of an observed amount relating to a change in the acceleration of the vehicle due to a driving operation, is greater than or equal to a predetermined threshold value.

In accordance with the information processing method of the eleventh aspect, even in a light collision, divergence may arise between the actually measured value and the predicted value of the acceleration, and therefore, a collision of the vehicle may be inferred accurately.

In a twelfth aspect of the present disclosure, in the above-described eleventh aspect may be configured such that, in a case in which acceleration relating to the acceleration difference is acceleration inputted to the vehicle from a road surface through a tire, the estimated value is not employed in determining a collision of the vehicle.

In accordance with the information processing method of the twelfth aspect, a collision of the vehicle may be inferred accurately by not using input, which is from the road surface through a tire and which may be a determining error, as an actually measured value of the acceleration in the determining of a collision.

In a thirteenth aspect of the present disclosure, in the above-described twelfth aspect, wheel speed differences, which are respective differences between actually measured values of respective wheel speeds of four wheels that are front and rear wheels of the vehicle, and estimated values of respective wheel speeds of the four wheels derived on the basis of the observed amount, are derived, and, after a change in the wheel speed difference, in either of a case in which the acceleration difference changes or a case in which wheel speed differences of the front wheels and the rear wheels change in order, it may be determined that acceleration relating to the acceleration difference is acceleration inputted from a road surface through a tire. Due to the above, components which may give rise to a determining error may be excluded from the acceleration.

A fourteenth aspect of the present disclosure is a non-transitory computer-readable medium storing an information processing program causing a computer to function as: an estimating section that determines that a vehicle has collided in a case in which an acceleration difference, which is a difference between an actually measured value of acceleration of the vehicle detected by an inertial measurement section and an estimated value of acceleration of the vehicle derived on the basis of an observed amount relating to a change in acceleration of the vehicle due to a driving operation detected by a detecting section, is greater than or equal to a predetermined threshold value.

The estimated value of the acceleration, which is derived on the basis of an observed amount relating to a change in the acceleration of the vehicle due to a driving operation, is the estimated value of the acceleration of the vehicle due to a driving operation. Further, the acceleration of the vehicle that arises at the time of a collision differs from a change in acceleration that is due to a driving operation. Accordingly, it may be determined that the vehicle has collided in a case in which the difference between the actually measured value of the acceleration of the vehicle that is detected by the inertial measurement section, and an estimated value of the acceleration of the vehicle that is derived on the basis of an observed amount relating to a change in the acceleration of the vehicle due to a driving operation, is greater than or equal to a predetermined threshold value.

In accordance with the non-transitory computer-readable medium storing the information processing program of the fourteenth aspect, even in a light collision, divergence can arise between the actually measured value and the predicted value of the acceleration, and therefore, a collision of the vehicle may be inferred accurately.

In a fifteenth aspect of the present disclosure, in the above-described fourteenth aspect may be configured such that, in a case in which acceleration relating to the acceleration difference is acceleration inputted to the vehicle from a road surface through a tire, the estimated value is not employed in determining a collision of the vehicle.

In accordance with the non-transitory computer-readable medium storing the information processing program of the fifteenth aspect, a collision of the vehicle can be inferred accurately by not using input, which is from the road surface through a tire and which may be a determining error, as an actually measured value of the acceleration in the determining of a collision.

In a sixteenth aspect of the present disclosure, in the above-described fifteenth aspect, wheel speed differences, which are respective differences between actually measured values of respective wheel speeds of four wheels that are front and rear wheels of the vehicle, and estimated values of respective wheel speeds of the four wheels derived on the basis of the observed amount, are derived, and, after a change in the wheel speed difference, in either of a case in which the acceleration difference changes or a case in which wheel speed differences of the front wheels and the rear wheels change in order, it may be determined that acceleration relating to the acceleration difference is acceleration inputted from a road surface through a tire. Due to the above, components which may give rise to a determining error may be excluded from the acceleration.

According to the above aspects, the information processing device, information processing method, and non-transitory computer-readable medium storing information processing program of the present disclosure may accurately detect light collisions.

### BRIEF DESCRIPTION OF THE DRAWINGS

Exemplary embodiments will be described in detail based on the following figures, wherein:

FIG. 1 is a schematic drawing illustrating the configuration of an information processing device relating to an exemplary embodiment;

FIG. 2 is a block drawing illustrating the configuration of a vehicle;

FIG. 3 is a block drawing illustrating an example of concrete configurations of a calculating server relating to the present exemplary embodiment;

FIG. 4 is a functional block drawing of a CPU of the calculating server;

FIG. 5 is a functional block drawing of the CPU of the calculating server after learning for acceleration estimation;

FIG. 6 is a functional block drawing of the CPU of the calculating server after learning for wheel speed estimation;

FIG. 7 is a functional block drawing of the CPU of the calculating server after learning for road surface input estimation;

FIG. 8 is a flowchart illustrating an example of processings at the calculating server relating to the present exemplary embodiment;

FIG. 9 is a schematic drawing of a case in which accident determining is carried out on the basis of elements that are an acceleration difference, an FL wheel speed difference, an RL wheel speed difference, pedal operation by the driver, latitude/longitude, and the like;

FIG. 10 is a schematic drawing at the time of carrying out accident determination on the basis of differences between actually measured values and estimated values estimated by an RNN;

FIG. 11 is a schematic drawing illustrating an example of values detected by various sensors;

FIG. 12A is an example of an image in a case in which the vehicle starts to ride-over a step;

FIG. 12B is an explanatory drawing illustrating a case in which, at the time when the vehicle rides-over a step, the left and right front wheels rotate idly and the speeds thereof increase, and thereafter, the left and right rear wheels rotate idly and the speeds thereof increase;

FIG. 13A is an example of an image in a case in which the vehicle passes over a rough road surface;

FIG. 13B is an explanatory drawing illustrating a case in which two maximum values of the acceleration difference are observed, and speeds of the front left wheel and the rear left wheel respectively increase immediately before the respective maximum values;

FIG. 14A is an example of an image that is acquired by an imaging device of the vehicle and is of a case in which the front right wheel of the vehicle rotates idly, when the driver depresses the accelerator pedal at the time of making a right turn over the step between a roadway and a sidewalk;

FIG. 14B is an explanatory drawing illustrating a case in which, as a result of the front right wheel of the vehicle rotating idly and the speed thereof increasing, divergence arises between actually measured values (the solid line) and estimated values (the dotted line) of the wheel speed at the front right wheel;

FIG. 15A is an example of an image that is acquired by the imaging device of the vehicle and is of a case in which unloading (pitching) of the rear left wheel of the vehicle arises;

FIG. 15B is an explanatory drawing illustrating a case in which, as a result of the rear left wheel of the vehicle rotating idly, divergence arises between actually measured values (the solid line) and estimated values (the dotted line) of the wheel speed at the rear left wheel;

FIG. 16 is a block drawing illustrating an example of employment of the information processing device relating to the present exemplary embodiment; and

FIG. 17 is a block drawing illustrating another example of employment of the information processing device relating to the present exemplary embodiment.

### DETAILED DESCRIPTION

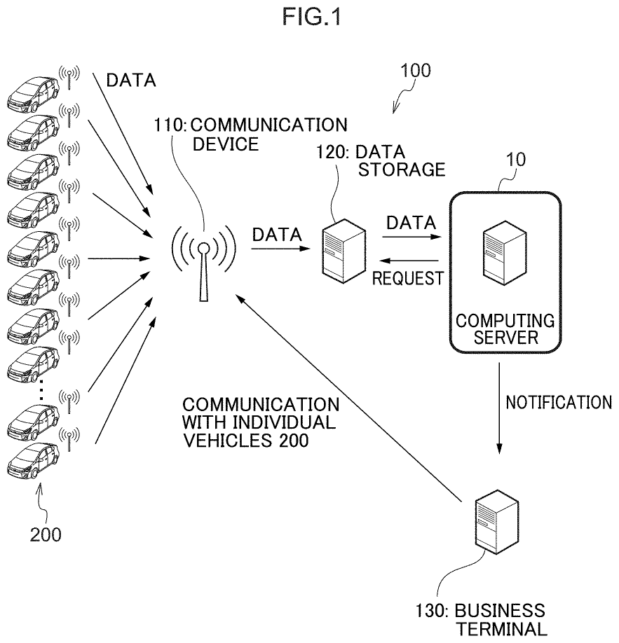

An information processing device 100 relating to a present exemplary embodiment is described hereinafter by using FIG. 1. The information processing device 100 illustrated in FIG. 1 includes: a communication device 110 that acquires data from plural vehicles 200 that are so-called connected cars that have the function of being continuously connected to a network; a data storage 120 that accumulates data received by the communication device 110; a computing server 10 that asks the data storage 120 for data needed for machine learning using a neural network, and that, by the machine learning that is carried out on the basis of the data acquired from the data storage 120, constructs an acceleration estimating model for estimating acceleration of the vehicle 200, and, on the basis of the constructed acceleration estimating model and the data acquired from the data storage 120, predicts the acceleration of the vehicle 200; and a business terminal 130 that is configured so as to be able to communicate with the individual vehicles 200 via the communication device 110 on the basis of notifications from the computing server 10.

As will be described later, the data storage 120 is a data server that has a database, and the computing server 10 is a computer that can execute advanced computing processings at high speed. The data storage 120 and the computing server 10 each may be a unit server, or may be a cloud that can disperse the processing load. The data storage 120 and the computing server 10 may be the same server. The business terminal 130 is not a requisite configuration, and may be omitted depending on the mode of the services relating to the vehicles 200.

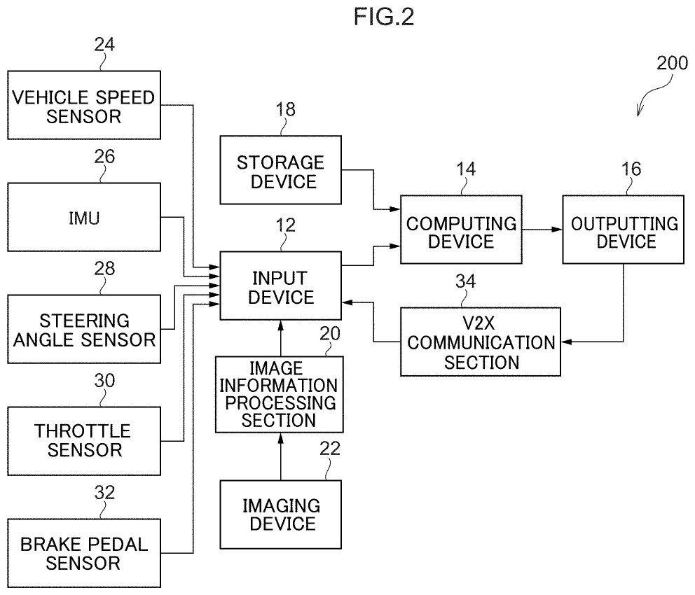

FIG. 2 is a block drawing illustrating the configuration of the vehicle 200. The vehicle 200 is configured by: a storage device 18 that stores data needed for computing by a computing device 14 and the results of computing by the computing device 14; an image information processing section 20 that derives behaviors of the vehicle 200 from image information acquired by an imaging device 22; an input device 12 to which are inputted the information relating to the behaviors of the vehicle 200 that were derived by the image information processing section 20, the vehicle longitudinal speed detected by a vehicle speed sensor 24, the deviation and acceleration of the azimuth angle of the vehicle 200 detected by an IMU (inertial measurement unit) 26, the steering angle of the vehicle 200 detected by a steering angle sensor 28, the throttle opening degree of the vehicle 200 detected by a throttle sensor 30, the force of depressing the brake pedal of the vehicle 200 detected by a brake pedal sensor 32, and information acquired by a V2X communication section 34 by wireless communication; the computing device 14 that, on the basis of inputted data that was inputted from the input device 12 and data stored in the storage device 18, estimates the acceleration of the vehicle 200 as needed; and an outputting device 16 that outputs the results of computing of the computing device 14 to the V2X communication section 34. Further, a master cylinder sensor, which detects the pressure within the master cylinder of the brakes, may be provided separately at the vehicle 200 in addition to the brake pedal sensor 32.

As mentioned above, the vehicle 200 is a so-called connected car, but, if not a connected car, may be a vehicle that is retrofitted with a communicator that is installed afterwards such as a so-called transaction log or the like that analyzes/utilizes traveling data transmitted from onboard equipment installed in the vehicle 200, and various sensors that acquire traveling data.

The imaging device 22 relating to the present exemplary embodiment is an onboard camera or the like, and acquires image data of the periphery of the vehicle 200. Further, the vehicle speed sensor 24 is configured so as to detect the respective four wheel speeds of the vehicle 200.

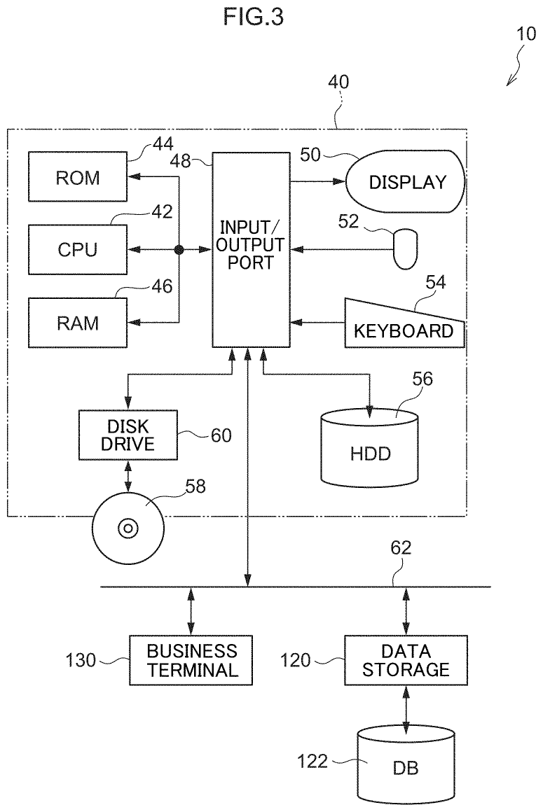

FIG. 3 is a block drawing illustrating an example of the concrete configuration of the computing server 10 relating to the exemplary embodiment of the present disclosure. The computing server 10 is configured to include a computer 40. The computer 40 has a CPU (Central Processing Unit) 42, a ROM (Read Only Memory) 44, a RAM (Random Access Memory) 46, and an input/output port 48. As an example, the computer 40 is preferably a type that can execute advanced computing processings at high speed.

At the computer 40, the CPU 42, the ROM 44, the RAM 46 and the input/output port 48 are connected to one another via various buses such as an address bus, a data bus, a control bus and the like. A display 50, a mouse 52, a keyboard 54, a hard disk (HDD) 56, and a disk drive 60, which can read-out information from various disks (e.g., a CD-ROM, a DVD, and the like) 58, are respectively connected to the input/output port 48 as various input/output devices.

A network 62 is connected to the input/output port 48, and information can be transmitted to and received from various devices that are connected to the network 62. In the present exemplary embodiment, the data storage 120, which is a data server to which a database (DB) 122 is connected, is connected to the network 62, and information can be transmitted to and received from the DB 122.

Time series data and the like of the plural vehicles 200, which data is acquired via the communication device 110, is stored in the DB 122. The storing of data into the DB 122 can be carried out by, other than via the communication device 110, registration therein by various devices that are connected to the computer 40 or the network 62.

The present exemplary embodiment describes that time series data and the like of the plural vehicles 200 are stored in the DB 122 that is connected to the data storage 120. However, the information of the DB 122 may be stored in the HDD 56 that is built into the computer 40, or in an external storage such as an externally-attached hard disk or the like.

A program relating to machine learning using a neural network is installed in the HDD 56 of the computer 40. In the present exemplary embodiment, due to the CPU 42 executing this program, machine learning starts, and a trained model that is based on machine learning is constructed. Moreover, the acceleration of the vehicle 200 is estimated by using the trained model that has been constructed. Further, the CPU 42 displays the results of processing by this program on the display 50.

There are several methods for installing the program, which relates to machine learning of the present exemplary embodiment, in the computer 40. For example, the program is stored together with a set-up program on a CD-ROM or a DVD or the like, and the disk is set in the disk drive 60, and the program is installed in the HDD 56 by the CPU 42 executing the set-up program. Or, the program may be installed in the HDD 56 by communication with another information processing device that is connected to the computer 40 via a dial-up line or the network 62.

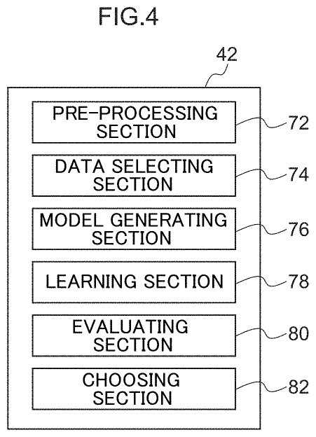

FIG. 4 is a functional block drawing of the CPU 42 of the computing server 10. The respective functions that are realized by the CPU 42 of the computing server 10 executing a program relating to machine learning are described. The program relating to machine learning has a pre-processing function that derives the accumulated value and the average value and the like of data that is transmitted-in from the vehicle 200, a data selecting function that selects data that is to be provided to the machine learning, a model generating function that generates an acceleration estimating model, a wheel speed estimating model and a road surface input estimating model, a learning function that provides the selected data to a candidate model as teaching data, and executes machine learning, an evaluating function that evaluates the performance of the trained model by actually measured values (measured values) that are teaching data, and choosing function that chooses a trained model that has excellent performance. Due to the CPU 42 executing the program relating to machine learning that has these respective functions, the CPU 42 functions as a pre-processing section 72, a data selecting section 74, a model generating section 76, a learning section 78, an evaluating section 80 and a choosing section 82 as illustrated in FIG. 4.

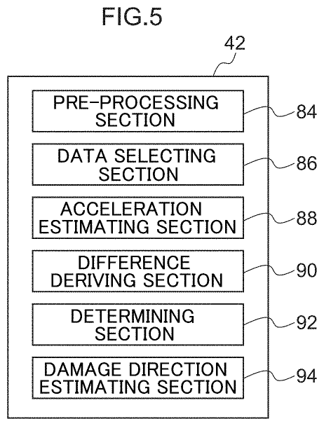

FIG. 5 is a functional block drawing of the CPU 42 of the computing server 10 after learning for acceleration estimation. The CPU 42 after learning has a pre-processing function that derives the accumulated value and the average value and the like of data that is transmitted-in from the vehicle 200, a data selecting function that selects data for collision sensing, an acceleration estimating function that estimates the acceleration of the vehicle 200 by using the trained model, a difference deriving function that derives the difference between an actually measured value and a presumed value, a determining function that determines the absence/presence of a collision, and a damage direction estimating function that estimates the damage direction due to the collision. Due to the CPU 42 executing the program relating to collision sensing that has these respective functions, the CPU 42 functions as a pre-processing section 84, a data selecting section 86, an acceleration estimating section 88, a difference deriving section 90, a determining section 92 and a damage direction estimating section 94 as illustrated in FIG. 5.

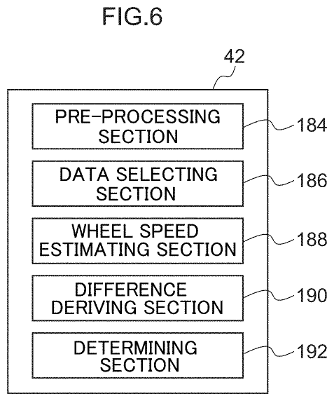

FIG. 6 is a functional block drawing of the CPU 42 of the computing server 10 after learning for wheel speed estimation. The CPU 42 after learning has a pre-processing function that derives the accumulated value and the average value and the like of data that is transmitted-in from the vehicle 200, a data selecting function that selects data for wheel speed estimation, a wheel speed estimating function that estimates the respective wheel speeds of the vehicle 200 by using the trained model, a difference deriving function that derives the difference between an actually measured value and a presumed value, and a determining function that determines the absence/presence of a collision and of road surface input that is force inputted from the road surface through a tire to the vehicle 200. Due to the CPU 42 executing the program relating to collision sensing that has these respective functions, the CPU 42 functions as a pre-processing section 184, a data selecting section 186, a wheel speed estimating section 188, a difference deriving section 190, and a determining section 192 as illustrated in FIG. 6.

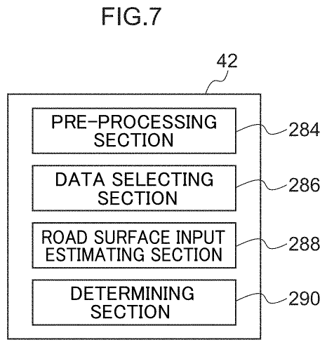

FIG. 7 is a functional block drawing of the CPU 42 of the computing server 10 after learning for road surface input estimation. The CPU 42 after learning has a pre-processing function that derives the accumulated value and the average value and the like of data that is transmitted-in from the vehicle 200, a data selecting function that selects data for road surface input estimation, a road surface input estimating function that estimates input from the road surface to the vehicle 200 through a tire by using the trained model, and a determining function that determines the absence/presence of road surface input. Due to the CPU 42 executing the program relating to collision sensing that has these respective functions, the CPU 42 functions as a pre-processing section 284, a data selecting section 286, a road surface input estimating section 288, and a determining section 290 as illustrated in FIG. 7.

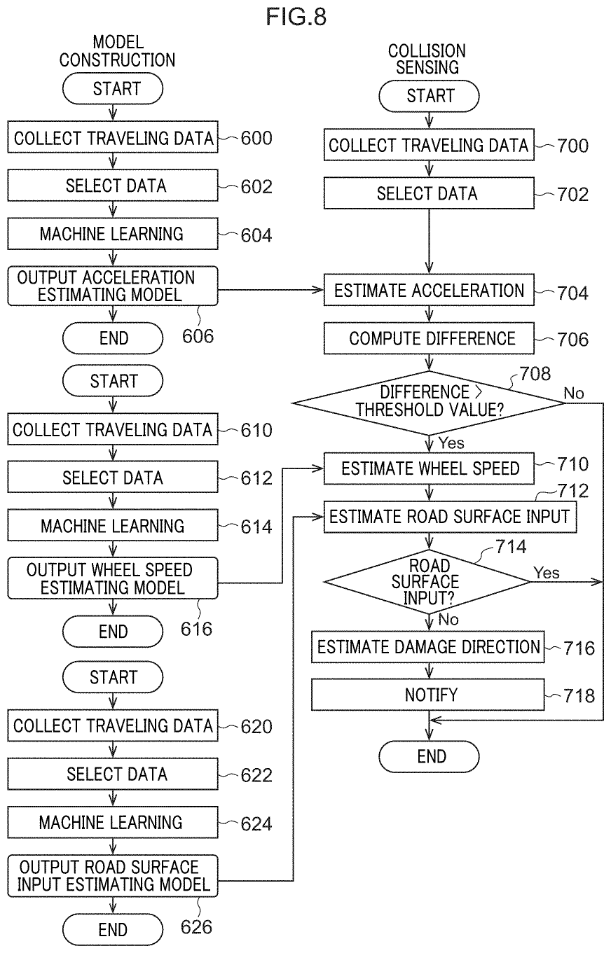

FIG. 8 is a flowchart illustrating an example of processings at the computing server 10 relating to the present exemplary embodiment. The left side of FIG. 8 is a thread relating to the constructing of a model for acceleration estimation (hereinafter called “acceleration estimating model”), a model for wheel speed estimation (hereinafter called “wheel speed estimating model”), and a model for estimating the absence/presence of road surface input (hereinafter called “road surface input estimating model”), respectively by machine learning. The right side of FIG. 8 is a thread relating to collision sensing by using the acceleration estimating model, the wheel speed estimating model and the road surface input estimating model after learning.

In step 600, in order to construct the acceleration estimating model, collecting of various traveling data of the plural vehicles 200 from the data storage 120 is carried out. Because data, which is needed for the pre-processing that derives the accumulated value and the average value and the like, exists among the various traveling data of the vehicles 200, this data is processed in step 600.

In step 602, data selection, which selects various traveling data that could become teaching data used in machine learning, is carried out. The various traveling data that could become teaching data include, for example: measured values of vehicle motion that mechanically relate to the longitudinal and lateral accelerations and the wheel speeds of the vehicle 200, beginning with the vehicle speed; operation states of vehicle motion control that are causes of increasing/decreasing the longitudinal and lateral accelerations and the wheel speeds of the vehicle 200, beginning with the ABS (Antilock Braking System); control signals that express driving operations by the driver that are causes of increasing/decreasing the longitudinal and lateral accelerations and the wheel speeds such as the pedals and the steering wheel and the like of the vehicle 200; control signals that express operations of power units that are causes of increasing/decreasing the longitudinal and lateral accelerations and the wheel speeds such as the engine and the like; and the like. In addition, measured values of the vehicle exterior environment that indirectly affect increasing/decreasing of the longitudinal and lateral accelerations and the wheel speeds such as the external air temperature and the wipers and the like, and control signals expressing operations of onboard equipment that are used depending on vehicle exterior environment, may be used. Data of the exterior that is generally disclosed by a meteorological agency or the like may be used as the measured values of the vehicle exterior environment, rather than values obtained by onboard sensors. In the data selection of step 602, various traveling data of the vehicles 200 under a broad range of conditions such as geographical regions and weather conditions and the like, are collected as the teaching data. Further, a robust acceleration estimating model can be constructed by incorporating into the teaching data, as much as possible, marked changes in the acceleration due to sudden braking or the like of the vehicle 200, extreme driving operations such as sudden turning of the steering wheel or the like, extreme motion states of the vehicle 200 such as high speeds or the like, control states that arise rarely such as ABS operation, and the like.

The teaching data may include acceleration data relating to accidents. Accidents are extremely rare, and, in principle, are difficult to predict from driving operations. Therefore, even if such data is included in the teaching data, the effects thereof the constructing of the model are minute.

In step 604, a candidate model for acceleration estimation is generated, and machine learning is executed by providing the candidate model with the selected various traveling data as teaching data. The model that executes machine learning in the present exemplary embodiment is a model that estimates acceleration of the vehicle 200 due to driving operations, and does not estimate acceleration due to a collision. In other words, acceleration that cannot be estimated is considered to be force from the vehicle exterior, and cases in which such acceleration arises are determined to be the possibility of a collision.

In step 604, individual models may be constructed per configuration of the vehicle 200, such as per vehicle type, year model, grade, tires that are used and the like. Further, models may be constructed in accordance with the country, season and weather in which the vehicle 200 is used. Or, a candidate model for acceleration estimation may be constructed by adding, to the above-described various traveling data, conditions relating to configurations of the vehicle 200 such as the vehicle type, the year model, the grade, the tires that are used and the like, and the country, season and weather in which the vehicle 200 is used.

In the present exemplary embodiment, for example, LSTM (Long Short-Term Memory) is employed in the architecture of an artificial regression neural network (RNN) that handles time series data. LSTM is architecture that can internally carry out processings such as (1) estimating the acceleration of the vehicle 200 from driving operations at a same point in time and the history of the driving operations, (2) estimating the acceleration of the vehicle 200 from the vehicle motions up until immediately before, (3) estimating the acceleration of the vehicle 200 from the correspondence between driving operations and vehicle motions up until immediately before, and the like.

In LSTM, sensor value vectors x_{1,t}, x_{2,t} are respectively defined as the vectors of the output values of the various sensors at time t (hereinafter called sensor values). The sensor value vector x_{1,t} has, as the elements thereof, actually measured values of vehicle motions that mechanically relate to the longitudinal and lateral accelerations and the wheel speeds of the vehicle 200, beginning with the vehicle speed. The sensor value vector x_{2,t} has, as the elements thereof, control signals expressing driving operations by the driver that are causes of increasing/decreasing the longitudinal and lateral accelerations and the wheel speeds such as the pedals and the steering wheel and the like of the vehicle 200, and control signals expressing operations of power units that are causes of increasing/decreasing the longitudinal and lateral accelerations and the wheel speeds such as the engine and the like, and the like.

Because the sensor value vectors x_{1,t}, x_{2,t} are time series data, sensor value matrix xₜ, which is for estimating acceleration of the vehicle 200 at time t, is defined as follows. In the sensor value matrix xₜ, m is an arbitrary mask value.

$${x}_{t} = [ \begin{matrix}{x}_{1 , t - n} , ⋯ , {x}_{1 , t - 1} , m \\ {x}_{2 , t - n} , ⋯ , {x}_{2 , t - 1} , {x}_{2 , t}\end{matrix} ]$$

In the present exemplary embodiment, model f that estimates acceleration of the vehicle 200 is constructed by using LSTM from time series data that is stored in the sensor value matrix xₜ. As model f of the present exemplary embodiment, there are model f_{fb}(xₜ) that estimates the longitudinal acceleration of the vehicle 200, and model fₗᵣ(xₜ) that estimates the lateral acceleration of the vehicle 200.

LSTM is an algorithm that predicts output from inputted time series data, and, through a process that updates past data to new data, constructs a model from which predicted values are outputted. By using, as teaching data, the sensor value matrix xₜ that is based on the data selected in step 602 as time series data, following model f_{fb}(xₜ) that estimates the longitudinal acceleration of the vehicle 200 and following model fₗᵣ(xₜ) that estimates the lateral acceleration of the vehicle 200 are constructed. In the present exemplary embodiment, as illustrated in FIG. 1, because a large amount of data relating to the sensor value matrix xₜ is collected from a large number of the vehicles 200, model construction by LSTM is easy.

The respective acceleration estimating models f_{fb}(xₜ), fₗᵣ(xₜ) may be constructed as statistical models in accordance with a non-neural network, or may be constructed on the basis of equations of motion of the vehicle 200.

â_{fb,t}=f_{fb}(xₜ)

â_{lr,t}=fₗᵣ(xₜ)
â_{fb,t}: estimated value of longitudinal acceleration
â_{lr,t}: estimated value of lateral acceleration

In step 606, the respective performances of the constructed models f_{fb}(xₜ), fₗᵣ(xₜ) are evaluated by new time series data that are actually measured values, and the models f_{fb}(xₜ), fₗᵣ(xₜ) in which the errors between the actually measured values and the estimated values are in an allowable range are outputted, and processing is ended. The models f_{fb}(xₜ), fₗᵣ(xₜ) that are outputted in step 606 are used in the collision sensing thread.

In step 610, in order to construct the wheel speed estimating model, collecting of various traveling data of plural vehicles 200 from the data storage 120 is carried out. In a case in which data, which is needed for the pre-processing that derives the accumulated value and the average value and the like, exists among the various traveling data of the vehicles 200, this data is processed in step 610.

In step 612, data selection, which selects various traveling data that could become teaching data to be used in machine learning, is carried out. The various traveling data that could become teaching data are the same various traveling data that are listed as examples in above-described step 602.

In step 614, a candidate model for wheel speed estimation is generated, and machine learning is executed by providing the candidate model with the selected various traveling data as teaching data. The model that executes machine learning in the present exemplary embodiment is a model that estimates the respective wheel speeds of the four wheels that are the front and rear wheels of the vehicle 200.

In step 614, in the same way as in step 604, individual models may be constructed per configuration of the vehicle 200, such as per vehicle type, year model, grade, tires that are used and the like. Further, models may be constructed in accordance with the country, season and weather in which the vehicle 200 is used. Or, a candidate model for wheel speed estimation may be constructed by adding, to the above-described various traveling data, conditions relating to configurations of the vehicle 200 such as the vehicle type, the year model, the grade, the tires that are used and the like, and the country, season and weather in which the vehicle 200 is used. In step 614, in the same way as in step 604, for example, LSTM is employed in the architecture of the RNN.

In step 614, in the same way as in step 604, sensor value vectors x_{1,t}, x_{2,t} are respectively defined as the vectors of the sensor values of time t. The sensor value vector x_{1,t} has, as the elements thereof, measured values of vehicle motions that mechanically relate to the longitudinal and lateral accelerations and the wheel speeds of the vehicle 200, beginning with the vehicle speed. The sensor value vector x_{2,t} has, as the elements thereof, control signals expressing driving operations by the driver that are causes of increasing/decreasing the longitudinal and lateral accelerations and the wheel speeds of the vehicle 200 such as the pedals and the steering wheel and the like, and control signals expressing operations of power units that are causes of increasing/decreasing the longitudinal and lateral accelerations and the wheel speeds such as the engine and the like, and the like.

In step 614, in the same way as in step 604, the sensor value matrix xₜ is defined. Then, model fᵥₓ(xₜ), which estimates the wheel speed of the vehicle 200 from the time series data that is stored in the sensor value matrix xₜ, is constructed by using LSTM. The wheel speed estimating model fᵥₓ(xₜ) may be constructed as a statistical model in accordance with a non-neural network, or may be constructed on the basis of equations of motion of the vehicle 200.

In step 616, the performance of the constructed model fᵥₓ(xₜ) is evaluated by new time series data that are actually measured values, and the model fᵥₓ(xₜ) in which the errors between the actually measured values and the estimated values are in an allowable range is outputted, and processing is ended. The model fᵥₓ(xₜ) that is outputted in step 616 is used in the collision sensing thread.

In step 620, in order to construct the road surface input estimating model, collecting of various traveling data of the plural vehicles 200 from the data storage 120 is carried out. In a case in which data, which is needed for the pre-processing that derives the accumulated value and the average value and the like, exists among the various traveling data of the vehicles 200, this data is processed in step 620.

In step 622, data selection, which selects various traveling data that could become teaching data used in machine learning, is carried out. The various traveling data that could become teaching data are the same various traveling data that are listed as examples in above-described step 602. However, in most cases, undulations of a road surface that give rise to road surface input arise at the same places, and therefore, data of projection/indentation positions of road surfaces that are based on position measuring data of a GPS (Global Positioning System) are included.

In step 624, a candidate model for road surface input estimation is generated, and machine learning is executed by providing the candidate model with the selected various traveling data as teaching data. The model that executes machine learning in the present exemplary embodiment is a model that estimates road surface input from information such as changes in the acceleration of the vehicle 200, changes in the respective wheel speeds of the four wheels that are the front and rear wheels, positions at which of projections/indentations exist on road surfaces, and the like.

In step 624, in the same way as in step 604, individual models may be constructed per configuration of the vehicle 200, such as per vehicle type, year model, grade, tires that are used and the like. Further, models may be constructed in accordance with the country, season and weather in which the vehicle 200 is used. Or, a candidate model for road surface input estimation may be constructed by adding, to the above-described various traveling data, conditions relating to configurations of the vehicle 200 such as the vehicle type, the year model, the grade, the tires that are used and the like, and the country, season and weather in which the vehicle 200 is used. In step 624, in the same way as in step 604, for example, LSTM is employed in the architecture of the RNN.

In step 624, in the same way as in step 604, a model that estimates road surface input of the vehicle 200 from time series data is constructed by using LSTM. The road surface input estimating model may be constructed as a statistical model in accordance with a non-neural network, or may be constructed on the basis of equations of motion of the vehicle 200.

In step 626, the performance of the constructed model is evaluated by new time series data that are actually measured values, and the model in which the errors between the actually measured values and the estimated values are in an allowable range is outputted, and processing is ended. The model that is outputted in step 626 is used in the collision sensing thread.

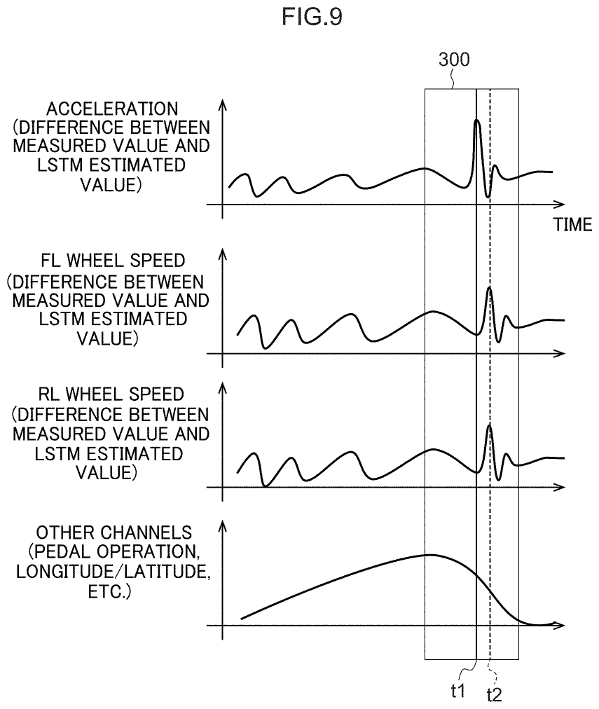

FIG. 9 is a schematic drawing in a case of carrying out accident determination on the basis of elements such as the difference between the measured value and the estimated value of acceleration (hereinafter called “acceleration difference”), the difference between the measured value and the estimated value of the FL (front left wheel) wheel speed (hereinafter called “FL wheel speed difference”), the difference between the actually measured value and the estimated value of the RL (rear right wheel) wheel speed (hereinafter called “RL wheel speed difference”), pedal operation by the driver, the longitude/latitude, and the like. In FIG. 9, selecting logics of road surface input and collision, which use time series data of the instant of an accident and before and after the accident, are considered.

In time band 300 of FIG. 9, marked fluctuations are exhibited in all of the acceleration difference, the FL wheel speed difference and the RL wheel speed difference. Further, after a marked change is exhibited in the acceleration difference at time point t1 within the time band 300, the FL wheel speed difference and the RL wheel speed difference respectively exhibit marked changes simultaneously at time point t2. As illustrated in FIG. 9, after a change in the acceleration difference, a case in which the difference between the measured value and the estimated value of the wheel speed (hereinafter called “wheel speed difference”) changes, or a case in which the wheel speed differences of the front wheels and the rear wheels or of the respective four wheels change, are cases in which collision due to an accident is surmised. Further, after a change in the wheel speed difference, a case in which the acceleration difference changes, or a case in which the wheel speed differences of the front wheels and the rear wheels change in order, are cases that can be determined to be road surface input.

In the present exemplary embodiment, at the time of carrying out machine learning by using LSTM, as illustrated in FIG. 1, a large number of instances of road surface input can be collected from a large number of the vehicles 200. Therefore, the acceleration difference due to road surface input is estimated from driving operations and wheel speed differences, and, by subtracting the acceleration that is due to road surface input from the estimated acceleration difference, acceleration that is due to a collision can be estimated.

Further, if displacement in the vertical direction of the position information of the vehicle 200 can be detected by a GPS or the like, the acceleration that relates to the acceleration difference at the time when this displacement is greater than or equal to a predetermined threshold value may be determined to be road surface input. Moreover, because places where there are undulations of the road surface and places where the slope changes sharply can be known, acceleration relating to the acceleration difference at the time when the vehicle 200 passes over such a place may be determined to be road surface input. Moreover, in a case in which similar wheel speed fluctuations and acceleration fluctuations arise at the same place at the plural vehicles 200, information of these places may be made into a database, and the acceleration that is detected at the time when the vehicle 200 passes over such a place may be determined to be road surface input.

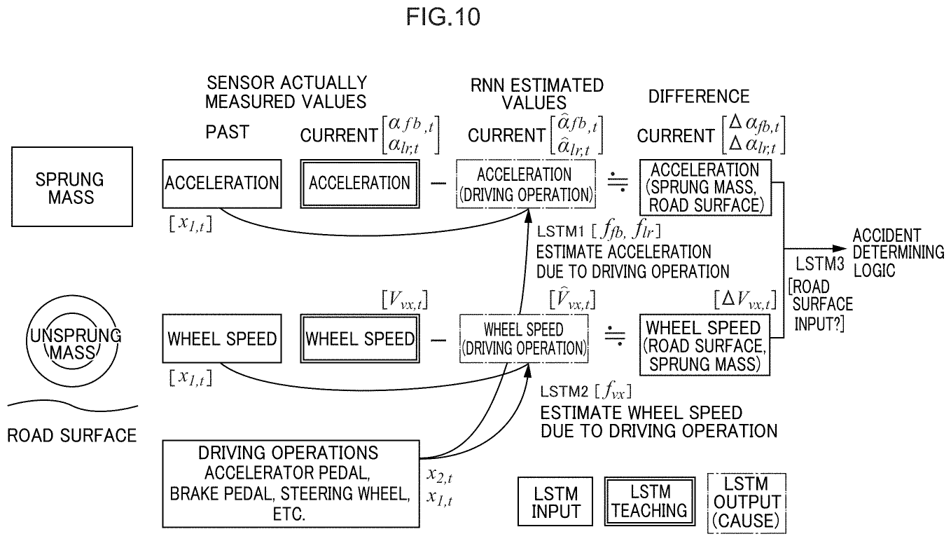

FIG. 10 is a schematic drawing at the time of carrying out accident determination on the basis of the differences between actually measured values and estimated values estimated by an RNN. The accelerations that can be estimated by the acceleration estimating models f_{fb}(xₜ), fₗᵣ(xₜ) that are constructed by an RNN are accelerations due to driving operations. Therefore, accelerations that cannot be estimated by the acceleration estimating models f_{fb}(xₜ), fₗᵣ(xₜ) are accelerations that are not due to driver operation, and are inferred to be acceleration that is due to a collision of the vehicle 200. Accordingly, if the differences Δa_{fb,t}, Δa_{lr,t} between actually measured values and estimated values estimated by an RNN are large, it is thought that acceleration that cannot be estimated by the acceleration estimating models f_{fb}(xₜ), fₗᵣ(xₜ) has arisen.

In the present exemplary embodiment, accident determination is carried out on the basis of the differences Δa_{fb,t}, Δa_{lr,t} between the actually measured values and the estimated values of the accelerations of the vehicle 200, but acceleration due to road surface input is included in the acceleration that is applied to the vehicle 200. In the present exemplary embodiment, in addition to estimating acceleration of the vehicle 200 by the acceleration estimating model constructed by LSTM1, wheel speeds of the vehicle 200 are estimated for the respective four wheels that are the front and rear wheels by the wheel speed estimating model constructed by LSTM2, and wheel speed differences Δv_{vx,t} are derived, and further, road surface input is estimated by the road surface input estimating model constructed by LSTM3, and final accident determination is carried out. The wheel speed difference Δv_{vx,t} may be derived by using a bypass filter, instead of a model constructed by an RNN. Further, accident determination may be carried out on the basis of differences between actually measured values and estimated values for each of the vertical acceleration, yaw rate, and vehicle speed of the vehicle 200.

An example of processings in the collision sensing thread is described on the basis of the above explanation. In step 700 of the collision sensing thread, collection of various traveling data from the data storage 120 is carried out individually for each of the vehicles 200. Among the various traveling data of the vehicles 200, there are data that are needed for the pre-processing that derives the accumulated values and the average values and the like, and therefore, this data is processed in step 700.

In step 702, data selection that selects various traveling data that are to be used in the acceleration estimation of the vehicle 200, is carried out. The various traveling data that are used in acceleration estimation are observed amounts relating to changes in the acceleration of the vehicle 200 due to driving operations, and include, for example: measured values of vehicle motions that are mechanically related to the longitudinal and lateral accelerations and the wheel speeds of the vehicle 200, beginning with the vehicle speed; operation states of vehicle motion control that are causes of increasing/decreasing the longitudinal and lateral accelerations and the wheel speeds, beginning with ABS; control signals that express driving operations by the driver that are causes of increasing/decreasing the longitudinal and lateral accelerations and the wheel speeds, such as the pedals and the steering wheel and the like of the vehicle 200; control signals that express operation of power units that are causes of increasing/decreasing the longitudinal and lateral accelerations and the wheel speeds, such as the engine and the like; and the like. In addition, measured values of the environment at the exterior of the vehicle that indirectly affect increasing/decreasing of the longitudinal and lateral accelerations and the wheel speeds such as the external air temperature and the wipers and the like, and control signals expressing operations of onboard equipment that are used depending on vehicle exterior environment, may be used. Data of the exterior that is generally disclosed by a meteorological agency or the like may be used as the measured values of the vehicle exterior environment, rather than values obtained by onboard sensors. In the data selection of step 602, various traveling data of the vehicles 200 under a broad range of conditions such as geographical regions or weather conditions or the like, are collected as the teaching data. Further, marked changes in the acceleration due to sudden braking or the like of the vehicle 200, extreme driving operations such as sudden turning of the steering wheel or the like, extreme motion states of the vehicle 200 such as high speeds or the like, control states that arise infrequently such as ABS operation, and the like are employed as much as possible.

In step 702, the speed of processing may be increased by filtering the various traveling data by a logic that is more simple than an RNN, and reducing the amount of processing of the stage thereafter. For example, as compared with using jerk, which is the time derivative of acceleration, as the predetermined threshold value, the system may be configured such that data in which jerk is less than a predetermined threshold value is not employed as significant data.

In step 704, the estimated value of the acceleration of the vehicle 200 is derived by using the acceleration estimating models f_{fb}(xₜ), fₗᵣ(xₜ) that were constructed by the model constructing thread.

In step 706, the respective differences Δa_{fb,t}, Δa_{lr,t} between the actually measured values of the accelerations that were detected by the IMU 26 and the estimated values of the accelerations that were estimated by using the acceleration estimating models f_{fb}(xₜ), fₗᵣ(xₜ) are derived as follows.

Δa_{fb,t}=a_{fb,t}−â_{fb,t}

Δa_{lr,t}=a_{lr,t}−â_{lr,t}

As described above, in the present exemplary embodiment, acceleration that cannot be estimated by the acceleration estimating models f_{fb}(xₜ), fₗᵣ(xₜ) that are constructed by an RNN using LSTM are considered to be force from the vehicle exterior. Accordingly, a case in which either of the differences Δa_{fb,t}, Δa_{lr,t} is greater than or equal to a predetermined threshold value is a case in which a large acceleration has been applied to the vehicle 200 from the vehicle exterior, and it can be inferred that an accident due to a collision has occurred. The predetermined threshold value is determined on the basis of the various traveling data that are collected from the plural vehicles 200. Further, a predetermined threshold value may be used in common for the differences Δa_{fb,t}, Δa_{lr,t} respectively, or there may be different values for the differences Δa_{fb,t}, Δa_{lr,t} respectively.

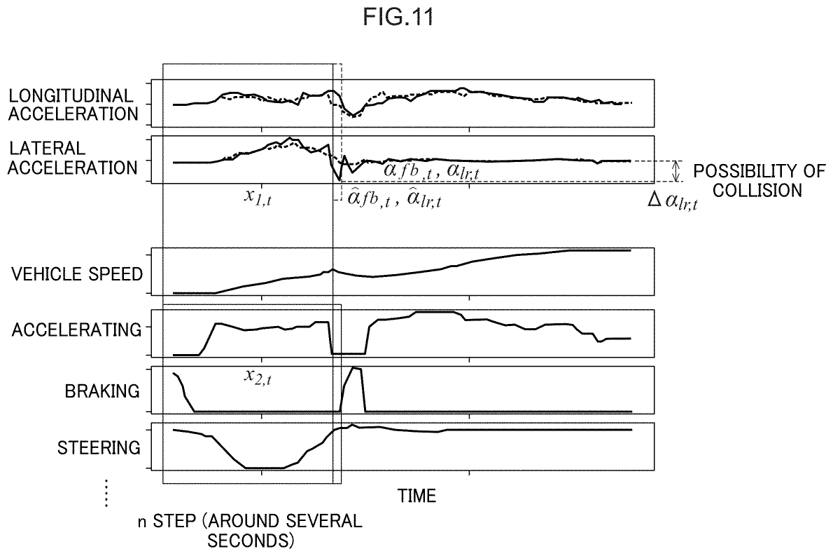

FIG. 11 is a schematic drawing illustrating an example of values detected by various sensors. In FIG. 11, actually measured values (the solid lines) that are measured by sensors such as the IMU 26 and the like, and estimated values (the broken lines) that are estimated by the acceleration estimating models f_{fb}(xₜ), fₗᵣ(xₜ), are illustrated for the longitudinal acceleration and the lateral acceleration.

In FIG. 11, there are cases in which the actually measured values and the estimated values in the lateral acceleration diverge greatly, and, in such cases, there is the possibility of a collision. In step 708, in a case in which either of the differences Δa_{fb,t}, Δa_{lr,t} is greater than or equal to a predetermined threshold value, it is determined that the vehicle 200 has collided. The predetermined threshold value is determined on the basis of statistics of actually measured values of behaviors of the vehicles 200. Further, as needed, an estimated input composite value at from the vehicle exterior may be derived by using the following formula, and, in a case in which the estimated input composite value at exceeds a predetermined composite value upper limit, it may be inferred that the vehicle 200 has collided.

aₜ=\sqrt{(Δa_{fb,t})²+(Δa_{lr,t})²}

In step 710, the respective wheel speeds of the four wheels that are the front and rear wheels of the vehicle 200 are estimated by using the wheel speed estimating model that was constructed by LSTM 2.

In step 712, acceleration relating to road surface input is estimated by using the road surface input estimating model constructed by LSTM 2. In step 712, for example, the wheel speed difference of the vehicle 200 is derived. Then, after a change in the wheel speed difference, in a case in which the acceleration difference derived in step 706 changes, or in a case in which the wheel speed differences of the front wheels and rear wheels change in order, that acceleration difference is considered to be due to road surface input. Further, after a change in the acceleration difference, in a case in which the wheel speed difference changes, or in a case in which the wheel speed differences of the front wheels and the rear wheels or of the respective four wheels fluctuate simultaneously, that acceleration difference is considered to be due to a collision.

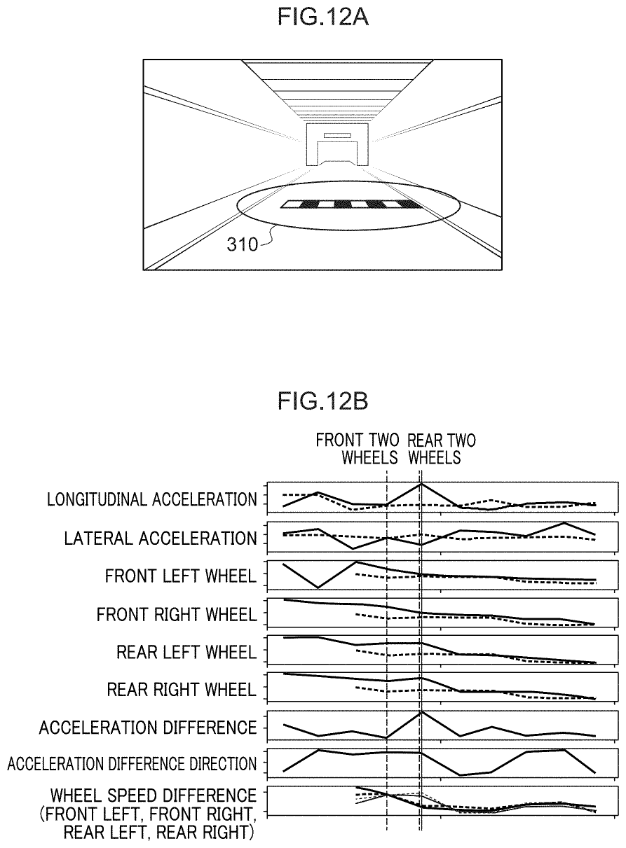

FIG. 12A is an example of an image in a case in which the vehicle 200 starts to ride-up over a step 310. FIG. 12B is an explanatory drawing illustrating a case in which, at the time when the vehicle 200 rides-up over the step 310, the left and right front wheels rotate idly and the speeds thereof increase, and thereafter, the left and right rear wheels rotate idly and the speeds thereof increase. In FIG. 12B, the solid lines are actually measured values, and the dotted lines are estimated values. Because FIG. 12B is a case in which the wheel speed differences of the front wheels and rear wheels change in order, it can be inferred that the acceleration difference arises due to road surface input.

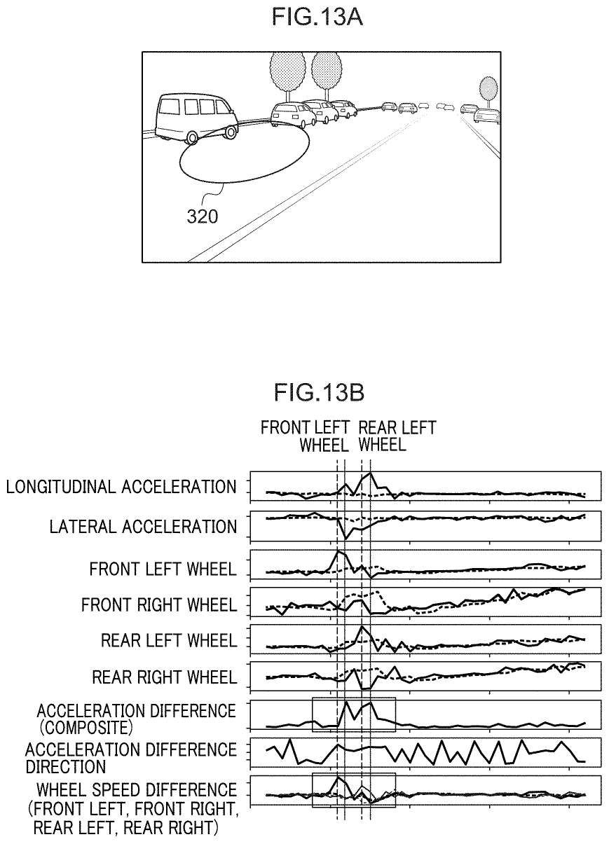

FIG. 13A is an example of an image in a case in which the vehicle 200 passes over a rough road surface 320. FIG. 13B is an explanatory drawing illustrating a case in which two maximum values of the acceleration difference are observed, and the speeds of front left wheel and the rear left wheel respectively increase immediately before the two maximum values respectively. In FIG. 13B, the solid lines are actually measured values, and the dotted lines are estimated values. FIG. 13B is a case in which, after a change in the wheel speed difference, the acceleration difference changes, and the wheel speed differences of the front wheels and the rear wheels change in order, and therefore, it can be inferred that the acceleration difference arises due to road surface input.

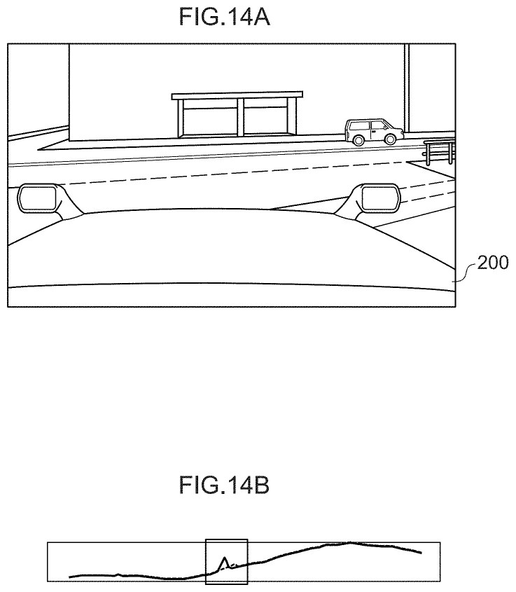

Acceleration that is not due to driving operations can be detected by image analysis as well. FIG. 14A is an example of an image that is acquired by the imaging device 22 of the vehicle 200 and is of a case in which the front right wheel of the vehicle 200 rotates idly at the time when the driver depresses the accelerator pedal at the time of making a right turn over the step between a roadway and a sidewalk. FIG. 14B is an explanatory drawing illustrating a case in which, as a result of the front right wheel of the vehicle 200 rotating idly and the speed thereof increasing, divergence arises between the actually measured value (the solid line) and the estimated value (the dotted line) of the wheel speed at the front right wheel. In FIG. 14A, the front right wheel of the vehicle 200 floats-up such that there is so-called three point road contact, and the front right wheel rotates idly.

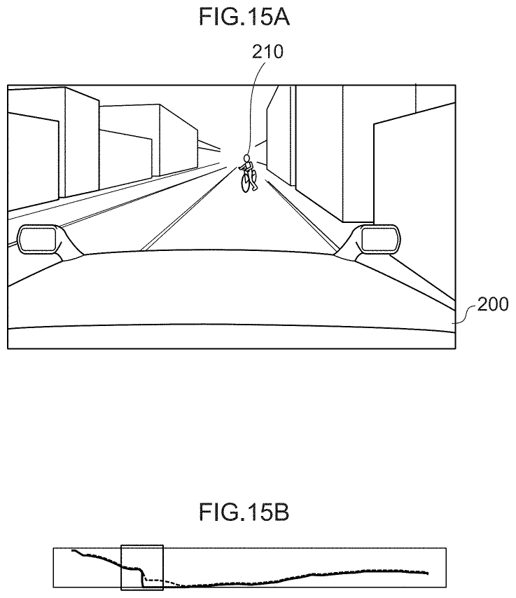

FIG. 15A is an example of an image that is acquired by the imaging device 22 of the vehicle 200 and is of a case in which unloading (pitching) of the rear left wheel of the vehicle 200 arises. FIG. 15B is explanatory drawing illustrating a case in which, as a result of the rear left wheel rotating idly, divergence arises between the actually measured value (the solid line) and the estimated value (the dotted line) of the wheel speed at the rear left wheel. The case illustrated in FIG. 15A and FIG. 15B is a case in which the driver of the vehicle 200 sees a person 210 who is riding a bicycle ahead, and carries out sudden braking and steering toward the left. As a result, the rear left wheel slips, the vehicle 200 decelerates due to the braking force of the brakes, and a difference arises between the actually measured value and the estimated value of the wheel speed of the rear left wheel.

In all of the cases of FIG. 14A, FIG. 14B, FIG. 15A and FIG. 15B, acceleration that is not caused by a driving operation may arise even though the vehicle 200 has not collided. In step 712, in addition to road surface input estimation, accident determination may be carried out by, for example, sudden behavior that is other than a collision of the vehicle 200 being extracted from the time series image data acquired by the imaging device 22, and the marked change in the actually measured value of the acceleration at the time when that behavior was effectuated being considered to be acceleration that does not relate to a collision and being excluded from the actually measured values. In the extracting of sudden behavior that is other than a collision of the vehicle 200 from image data, as an example, determination is carried out on the basis of positional changes per unit time in the image data of pixels (pixels of note) that show specific places, such as the four corners or the like, of the vehicle 200. In a case in which the positional change per unit time of pixels of note is greater than or equal to a predetermined positional change threshold value, it is determined that there is a sudden behavior of the vehicle 200. Moreover, if there no change in the shape of or the surface area of the set of pixels that show the vehicle 200 in the image data, it can be determined that there is sudden behavior that is other than a collision of the vehicle 200.

In step 714, in a case in which the acceleration difference is due to road surface input, processing is ended without using the acceleration that relates to this acceleration difference in the collision determination. In step 714, if the acceleration difference is not due to road surface input, processing moves on to step 716.

In step 716, the damage direction of the vehicle 200 is estimated by using the following formula. Given that the difference Δa_{fb,t} is the vector amount in the longitudinal direction and Δa_{lr,t} is the vector amount in the lateral direction, the quotient of the difference Δa_{fb,t} and the difference Δa_{lr,t} is the tangent of the angle expressing the damage direction. Accordingly, inverse tangent dₜ of the quotient of the difference Δa_{fb,t} and the difference Δa_{lr,t} is the angle expressing the damage direction. The damage direction may be estimated on the basis of, other than the direction of the acceleration, the displacement of the position information of the vehicle 200 detected by the GPS, or the changes in the respective wheel speeds of the vehicle 200.

$${d}_{t} = {tan}^{- 1} ( \frac{Δ {a}_{fb , t}}{Δ {a}_{lr , t}} )$$

In step 718, the computing server 10 notifies the business terminal 130 or the like of the results of determination, and ends the processing.

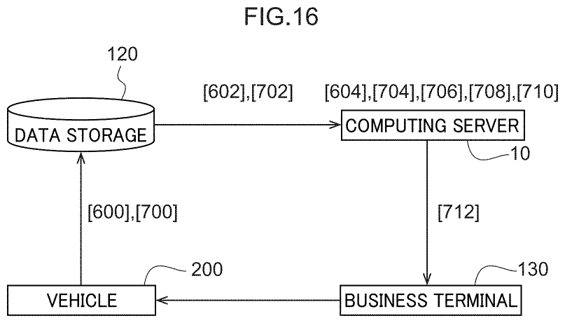

FIG. 16 is a block drawing illustrating an example of employing the information processing device 100 relating to the present exemplary embodiment. As illustrated in FIG. 16, the data storage 120 collects various traveling data of the vehicle 200 as in steps 600, 700 of FIG. 8.

The various traveling data of the vehicle 200 that are acquired by the data storage 120 are transmitted to the computing server, and selecting of the data is carried out as in steps 602, 702 of FIG. 8.

At the computing server 10, learning such as in step 604 of FIG. 8 is carried out, and the acceleration estimating models f_{fb}(xₜ), fₗᵣ(xₜ) are constructed. Then, by using the acceleration estimating models f_{fb}(xₜ), fₗᵣ(xₜ), acceleration estimation, deriving of the differences Δa_{fb,t}, Δa_{lr,t}, collision determining, and estimating of the damage direction that are illustrated in steps 704 through 710 of FIG. 8 are carried out.

Then, as in step 712 of FIG. 8, the computing server 10 notifies the business terminal 130 of the assessment of a used vehicle, maintenance of the vehicle 200, inspection of the vehicle 200, a record of operations of the vehicle 200, new car sales business, safety confirming calls, and the like.

In the employment example that is illustrated in FIG. 16, at the computing server 10, data collection and selecting, construction of the acceleration estimating models f_{fb}(xₜ), fₗᵣ(xₜ), acceleration estimation, deriving of the differences Δa_{fb,t}, Δa_{lr,t}, collision determining, and estimating of the damage direction are carried out. However, in order to reduce the load, the computing server 10 may carry out constructing of the acceleration estimating models f_{fb}(xₜ), fₗᵣ(xₜ) from the various traveling data of the vehicle 200 acquired from the data storage 120, and, at another server, the data collection and selecting, the acceleration estimating, the deriving of the differences Δa_{fb,t}, Δa_{lr,t}, the collision determining, and the estimating of the damage direction relating to steps 700 through 710 of FIG. 6 may be carried out by using the acceleration estimating models f_{fb}(xₜ), fₗᵣ(xₜ) that were constructed at the computing server 10.

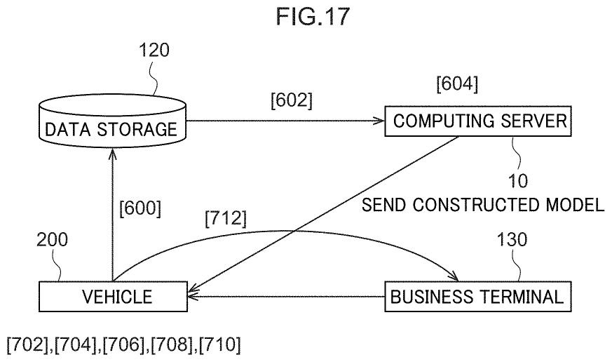

FIG. 17 is a block drawing illustrating another example of employment of the information processing device 100 relating to the present exemplary embodiment. As illustrated in FIG. 17, the data storage 120 collects various traveling data of the vehicle 200 as in step 600 of FIG. 8.

The various traveling data of the vehicle 200 that are acquired by the data storage 120 are transmitted to the computing server, and selecting of the data is carried out as in step 602 of FIG. 8.

At the computing server 10, learning such as in step 604 of FIG. 8 is carried out, and the acceleration estimating models f_{fb}(xₜ), fₗᵣ(xₜ) are constructed. Then, the constructed acceleration estimating models f_{fb}(xₜ), fₗᵣ(xₜ) are transmitted to the vehicle 200.

At the vehicle 200, the selecting of data, the acceleration estimation, the deriving of the differences Δa_{fb,t}, Δa_{lr,t}, the collision determining, and the estimating of the damage direction that are illustrated in steps 702 through 710 of FIG. 8 are carried out by the computing device 14.

Then, as in step 712 of FIG. 8, the vehicle 200 notifies the business terminal 130 of the assessment of a used vehicle, maintenance of the vehicle 200, inspection of the vehicle 200, a record of operations of the vehicle 200, new car sales business, safety confirming calls, and the like.

In the employment example that is illustrated in FIG. 17, because the collision sensing is carried out at the vehicle 200, there is no need for the data storage 120 to acquire the various traveling data from the vehicle 200 and transfer the acquired various traveling data to the computing server 10, and therefore, the capacity of the data storage 120 can be reduced.

As described above, in the present exemplary embodiment, it is determined that the vehicle 200 has collided in a case in which the difference between an actually measured value of the acceleration of the vehicle 200 that is detected at the IMU 26 or the like, and an estimated value of the acceleration of the vehicle 200 that is derived on the basis of an observed amount relating to a change in the acceleration of the vehicle 200 due to a driving operation, is greater than or equal to a predetermined threshold value.

The estimated value of the acceleration, which is derived on the basis of an observed amount relating to a change in the acceleration of the vehicle due to a driving operation, is an estimated value of the acceleration of the vehicle 200 due to a driving operation. Further, the acceleration of the vehicle 200 that arises at the time of a collision is different than a change in acceleration that is due to a driving operation. Accordingly, it is determined that the vehicle 200 has collided in a case in which the difference between an actually measured value of the acceleration of the vehicle 200 that is detected at the IMU 26 or the like, and an estimated value of the acceleration of the vehicle 200 that is derived on the basis of an observed amount relating to a change in the acceleration of the vehicle 200 due to a driving operation, is greater than or equal to a predetermined threshold value.

Even in a light collision, divergence can arise between the actually measured value and the predicted value of the acceleration, and therefore, a collision of the vehicle 200 can be inferred accurately.

In the present exemplary embodiment, individual acceleration estimating models may be constructed for each configuration of the vehicle 200, such as per vehicle type, year model, grade, tires that are used and the like, and further, models may be constructed in accordance with the country, season and weather in which the vehicle 200 is used. Or, a candidate model for acceleration estimation may be constructed by adding, to the above-described various traveling data, conditions relating to configurations of the vehicle 200 such as the vehicle type, the year model, the grade, the tires that are used and the like, and the country, season and weather in which the vehicle 200 is used. The accuracy of collision sensing can be improved by constructing the acceleration estimating model by subdividing the conditions.

Further, because the vehicle 200 that is a connected car is used in collecting the various traveling data, collision sensing can be executed at the computing server 10 or the like that exists remotely from the vehicle 200, without requiring the retrofitting of devices to the vehicle 200.

In the present exemplary embodiment, the acceleration estimating model is constructed by machine learning that is based on so-called big data that is acquired from a large number of the vehicles 200. Therefore, a model that can accurately estimate the acceleration of the vehicle 200 due to driving operations can be constructed.

In the present exemplary embodiment, the model f_{fb}(xₜ) that estimates the longitudinal acceleration of the vehicle 200 and the model fₗᵣ(xₜ) that estimates the lateral acceleration of the vehicle 200 are constructed, and the damage direction of the vehicle 200 can be estimated from the predicted value of the acceleration in the longitudinal direction and the acceleration in the lateral direction of the vehicle 200. Moreover, the results of inferring a collision accident and the estimated results of the damage direction of the vehicle 200 respectively can be useful in: describing the accident history in the sale of a used vehicle; guidelines for maintenance of business vehicles such as taxis and the like; estimating the absence/presence of a collision when a rental car is returned; providing notifications that the vehicle should be brought to a dealer or a repair shop; safety confirming notification from an insurance company in a case in which an accident is surmised; records of operations of autonomous vehicles; and the like.

Moreover, in the present exemplary embodiment, the wheel speeds of the vehicle 200 are estimated, and, from the form of the difference between the actually measured value and the estimated value of the wheel speed, the absence/presence of acceleration due to road surface input can be determined, and, from this determination, the accuracy of sensing a collision can be improved.

Note that the “detecting section” in the claims corresponds respectively to the “imaging device 22”, the “vehicle speed sensor 24”, the “steering angle sensor 28”, the “throttle sensor 30” and the “brake pedal sensor 32” of the detailed description of the specification. Further, the “inertial measurement section” in the claims corresponds to the “IMU 26” of the detailed description of the specification.

Note that any of various types of processors other than a CPU may execute the processings that are executed by the CPU reading-in software (programs) in the above-described exemplary embodiment. Examples of processors in this case include PLDs (Programmable Logic Devices) whose circuit configuration can be changed after production such as FPGAs (Field-Programmable Gate Arrays) and the like, and dedicated electrical circuits that are processors having circuit configurations that are designed for the sole purpose of executing specific processings such as ASICs (Application Specific Integrated Circuits) and the like, and the like. Further, the processings may be executed by one of these various types of processors, or may be executed by a combination of two or more of the same type or different types of processors (e.g., plural FPGAs, or a combination of a CPU and an FPGA, or the like). Further, the hardware configurations of these various types of processors are, more concretely, electrical circuits that combine circuit elements such as semiconductor elements and the like.

Further, the above exemplary embodiment describes an aspect in which the programs are stored in advance (are installed) in the disk drive 60 or the like, but the present disclosure is not limited to this. The programs may be provided in a form of being stored on a non-transitory storage medium such as a CD-ROM (Compact Disk Read Only Memory), a DVD-ROM (Digital Versatile Disk Read Only Memory), a USB (Universal Serial Bus) memory, or the like. Further, the programs may be in forms of being downloaded from an external device via a network.

(Supplementary Note 1)

An information processing device is configured to include:

a memory; and

at least one processor coupled to the memory, the least one processor being configured to:

determine that a vehicle has collided, in a case in which a difference between, an actually measured value of acceleration of the vehicle that is detected by an inertial measurement section, and an estimated value of acceleration of the vehicle that is derived on the basis of an observed amount relating to a change in acceleration of the vehicle due to a driving operation detected by a detecting section, is greater than or equal to a predetermined threshold value.

What is claimed is:

1. An information processing device comprising:
a memory; and
at least one processor coupled to the memory, the processor being configured to:
detect an observed amount relating to a change in acceleration of a vehicle due to a driving operation;
detect an actually measured value of acceleration of the vehicle; and
determine that the vehicle has collided in a case in which an acceleration difference, which is a difference between an actually measured value of acceleration of the vehicle and an estimated value of acceleration of the vehicle derived on the basis of the observed amount, is greater than or equal to a predetermined threshold value.

2. The information processing device of claim 1, wherein the processor is configured to, in a case in which acceleration relating to the acceleration difference is acceleration that is inputted to the vehicle from a road surface through a tire, not employ the estimated value in determining a collision of the vehicle.

3. The information processing device of claim 2, wherein the processor is configured to:
detect respective wheel speeds of four wheels that the vehicle has, and
derive wheel speed differences, which are respective differences between actually measured values of respective wheel speeds of the four wheels that are front and rear wheels of the vehicle detected by the wheel speed detecting section, and estimated values of respective wheel speeds of the four wheels that are the front and rear wheels of the vehicle derived on the basis of the observed amount, and, after a change in the wheel speed difference, in either of a case in which the acceleration difference changes or a case in which wheel speed differences of the front wheels and the rear wheels change in order, determine that acceleration relating to the acceleration difference is acceleration inputted from a road surface through a tire.

4. The information processing device of claim 2, further comprising an imaging section that acquires image data of a periphery of the vehicle in time series,
wherein the processor is configured to consider acceleration, which relates to the acceleration difference at a time when sudden behavior of the vehicle is recorded in the image data acquired by the imaging section, to be acceleration that is inputted to the vehicle from a road surface through a tire.

5. The information processing device of claim 2, wherein the processor is configured to, in a case in which vertical direction displacement of position information of the vehicle derived on the basis of information from a satellite is greater than or equal to a predetermined value, determine that acceleration, which relates to the acceleration difference, is acceleration that is inputted from a road surface through a tire.

6. The information processing device of claim 2, wherein the processor is configured to refer to a database of places at which there are undulations of a road surface, places at which a slope changes sharply, and places at which changes in acceleration arise at a plurality of vehicles, and determine that acceleration relating to the acceleration difference is acceleration inputted from a road surface through a tire.

7. The information processing device of claim 1, wherein the processor is configured to:
detect acceleration in a longitudinal direction and acceleration in a lateral direction of the vehicle respectively, and
be able to respectively derive an estimated value of acceleration in the longitudinal direction and an estimated value of acceleration in the lateral direction of the vehicle on the basis of the observed amount, and determine that the vehicle has collided in a case in which either of a difference between an actually measured value of acceleration in the longitudinal direction of the vehicle detected by the inertial measurement section and an estimated value of acceleration in the longitudinal direction of the vehicle, or a difference between an actually measured value of acceleration in the lateral direction of the vehicle detected by the inertial measurement section and an estimated value of acceleration in the lateral direction of the vehicle, is greater than or equal to a predetermined threshold value.

8. The information processing device of claim 7, wherein the processor is configured to estimate a damage direction of the vehicle on the basis of a quotient of a difference between the actually measured value of acceleration in the longitudinal direction of the vehicle detected by the inertial measurement section and the estimated value of acceleration in the longitudinal direction of the vehicle, and a difference between the actually measured value of acceleration in the lateral direction of the vehicle detected by the inertial measurement section and the estimated value of acceleration in the lateral direction of the vehicle.

9. The information processing device of claim 1, wherein the processor is configured to construct a model that estimates acceleration of the vehicle, on the basis of observed amounts relating to changes in acceleration of a plurality of vehicles and actually measured values of acceleration of the plurality of vehicles, which are acquired in advance.

10. The information processing device of claim 1, wherein the observed amount includes measured values of vehicle motions of the vehicle and control signals relating to driving operation amounts of the vehicle.

11. An information processing method comprising:
detecting, by a detecting section, an observed amount relating to a change in acceleration of a vehicle due to a driving operation;
detecting, by an inertial measurement section, an actually measured value of acceleration of the vehicle; and
determining that the vehicle has collided in a case in which an acceleration difference, which is a difference between the actually measured value of acceleration of the vehicle and an estimated value of acceleration of the vehicle derived on the basis of the observed amount, is greater than or equal to a predetermined threshold value.

12. The information processing method of claim 11, wherein, in a case in which acceleration relating to the acceleration difference is acceleration inputted to the vehicle from a road surface through a tire, the estimated value is not employed in determining a collision of the vehicle.

13. The information processing method of claim 12, wherein wheel speed differences, which are respective differences between actually measured values of respective wheel speeds of four wheels that are front and rear wheels of the vehicle, and estimated values of respective wheel speeds of the four wheels derived on the basis of the observed amount, are derived, and, after a change in the wheel speed difference, in either of a case in which the acceleration difference changes or a case in which wheel speed differences of the front wheels and the rear wheels change in order, it is determined that acceleration relating to the acceleration difference is acceleration inputted from a road surface through a tire.

14. A non-transitory computer-readable medium storing an information processing program causing a computer to function as:
an estimating section that determines that a vehicle has collided in a case in which an acceleration difference, which is a difference between an actually measured value of acceleration of the vehicle detected by an inertial measurement section and an estimated value of acceleration of the vehicle derived on the basis of an observed amount relating to a change in acceleration of the vehicle due to a driving operation detected by a detecting section, is greater than or equal to a predetermined threshold value.

15. The non-transitory computer-readable medium storing the information processing program of claim 14, wherein, in a case in which acceleration relating to the acceleration difference is acceleration inputted to the vehicle from a road surface through a tire, the estimated value is not employed in determining a collision of the vehicle.

16. The non-transitory computer-readable medium storing the information processing program of claim 15, wherein wheel speed differences, which are respective differences between actually measured values of respective wheel speeds of four wheels that are front and rear wheels of the vehicle, and estimated values of respective wheel speeds of the four wheels derived on the basis of the observed amount, are derived, and, after a change in the wheel speed difference, in either of a case in which the acceleration difference changes or a case in which wheel speed differences of the front wheels and the rear wheels change in order, it is determined that acceleration relating to the acceleration difference is acceleration inputted from a road surface through a tire.
